(19) United States
(12) Patent Application Publication
(10) Pub. No.: US 2011/0156261 A1
(43) Pub. Date: Jun. 30, 2011

(54) INTEGRATED CIRCUIT PACKAGE AND METHOD OF MAKING SAME

(76) Inventors: Christopher James Kapusta, Delanson, NY (US); Glenn Forman, Niskayuna, NY (US); James Sabatini, Scotia, NY (US)

(21) Appl. No.: 12/410,255

(22) Filed: Mar. 24, 2009

(51) Int. Cl. H01L 23/48; H01L 21/50

(52) U.S. Cl. 257/773; 438/118; 438/107; 257/E23.01; 257/E21.499

(57) ABSTRACT

An integrated circuit package includes a first dielectric layer comprising a dielectric film having a first side and a second side, the first side having a plurality of contact locations and a plurality of non-contact locations. The package includes a plurality of components, each component having a first surface and a second surface, wherein the first surface of each of the plurality of components is affixed to a corresponding one of the plurality of contact locations of the dielectric film absent a layer of adhesive therebetween that is distinct from a material of the dielectric film.

### GOVERNMENT RIGHTS IN THE INVENTION

The U.S. Government has a paid-up license in this invention and the right in limited circumstances to require the patent owner to license others on reasonable terms as provided for by the terms of Government Contract No. FA9453-04-C-0003 awarded by the Air Force Research Laboratory.

### BACKGROUND OF THE INVENTION

The invention relates generally to integrated circuit packages and, more particularly, to an apparatus and method of fabricating a package having a reduced thickness.

Chip scale packages or integrated circuit (IC) packages are typically fabricated having a number of dies or chips encapsulated within an embedding compound. A laminate re-distribution layer covers the active side of each of the plurality of dies and typically comprises a dielectric laminate material, such as Kapton, affixed to the plurality of dies using a layer of adhesive. The plurality of dies are electrically connected to an input/output system by way of metal interconnects routed through a plurality of additional laminate re-distribution layers. Each additional re-distribution layer increases the overall thickness of the IC package.

Advancements in IC packaging requirements pose challenges to the existing embedded chip build-up process. That is, it is desired in many current embedded chip packages to have an increased number of re-distribution layers, with eight or more re-distribution layers being common. The advancements are driven by ever-increasing needs for achieving better performance, greater miniaturization, and higher reliability. Thus, as ICs become increasingly smaller and yield better operating performance, packaging technology has correspondingly evolved from leaded packaging, to laminate-based ball grid array (BGA) packaging, to chip-scale packaging (CSP), to flipchip packages, and to embedded chip build-up packaging. However, these stacking methods typically result in an unacceptably thick package height.

Furthermore, due to the small size and complexity of IC packages, the process for fabricating IC packages is typically expensive and time consuming. One method of fabrication typically begins by placing the plurality of dies or chips active-side down onto a sacrificial layer, which serves to position and support the plurality of dies during the encapsulation process. Once the encapsulant has cured, the sacrificial layer is removed, which adds time and cost to the process due to added steps and materials.

Accordingly, there is a need for a simplified method for fabricating IC packages. There is a further need for a method for fabricating more complex and intricate IC packages while minimizing the thickness of the chip scale package.

It would therefore be desirable to have an apparatus and streamlined method of fabricating a complex IC package having a reduced thickness.

### BRIEF DESCRIPTION OF THE INVENTION

The invention provides a system and method of fabricating components of an IC package having a reduced thickness.

In accordance with one aspect of the invention, an apparatus includes a first dielectric layer comprising a dielectric film having a first side and a second side, the first side having a plurality of contact locations and a plurality of non-contact locations. The apparatus also includes a plurality of components, each component having a first surface and a second surface, wherein the first surface of each of the plurality of components is affixed to a corresponding one of the plurality of contact locations of the dielectric film absent a layer of adhesive therebetween that is distinct from a material of the dielectric film.

In accordance with another aspect of the invention, an apparatus includes a first dielectric film having a first side and a second side. The apparatus also includes a first component affixed to a first portion of the first side of the first dielectric film via an adhesive property of the first dielectric film and absent a layer of adhesive between the first component and the first dielectric film that is distinct from a property of the first dielectric film.

In accordance with another aspect of the invention, a method of fabricating an integrated circuit (IC) package includes providing a first dielectric film having a first contact side and a second contact side, the first contact side having at least one contact portion and at least one non-contact portion. The method also includes attaching an active surface of at least one electrical component to the at least one contact portion of the first contact side of the first dielectric film via an adhesive property of the first dielectric film and absent a layer of adhesive between the at least one electrical component and the first dielectric film distinct from a property of the first dielectric film. The method further includes curing the first dielectric film and removing a liner of the first dielectric film to expose the second contact side of the first dielectric film.

Various other features and advantages will be made apparent from the following detailed description and the drawings.

### BRIEF DESCRIPTION OF THE DRAWINGS

The drawings illustrate embodiments presently contemplated for carrying out the invention.

In the drawings:

FIG. 1 is a top view of a plurality of dies affixed to a dielectric film layer according to an embodiment of the invention.

FIGS. 2-12 are schematic diagrams showing steps of making an IC package incorporating in accordance with an embodiment of the invention.

### DETAILED DESCRIPTION OF THE PREFERRED EMBODIMENT

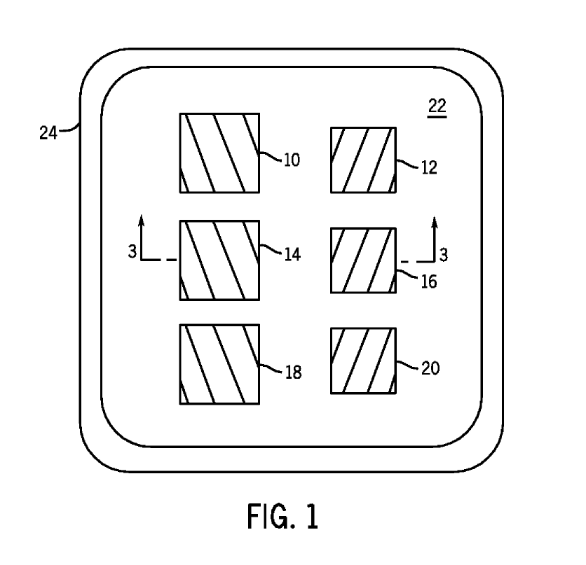

FIG. 1 is a top view of a plurality of dies or semiconductor chips 10, 12, 14, 16, 18, 20 positioned on a dielectric tape or film 22. As shown, dielectric film 22 may be stabilized using a frame 24 during the fabrication process such that plurality of dies 10-20 may be positioned thereon. In one embodiment, the height and/or width of each of the plurality of dies 10-20 may differ, which may result from, for example, a tolerance error between different dies. In addition, each of the plurality of dies 10-20 may comprise a different die type, such as, for example, a memory die type, a processing die type, a logic die type, and an application specific integrated circuit (ASIC) die type. Alternatively, each of dies 10-20 may be of the same die type and/or have a substantially similar height and/or width. While FIG. 1 shows a plurality of dies attached to the film 22, in another embodiment of the invention, a plurality of electronic components 10-20 other than a die, such as an active or passive electronic device may be attached to film 22 such that a multi-component module or layer may be formed.

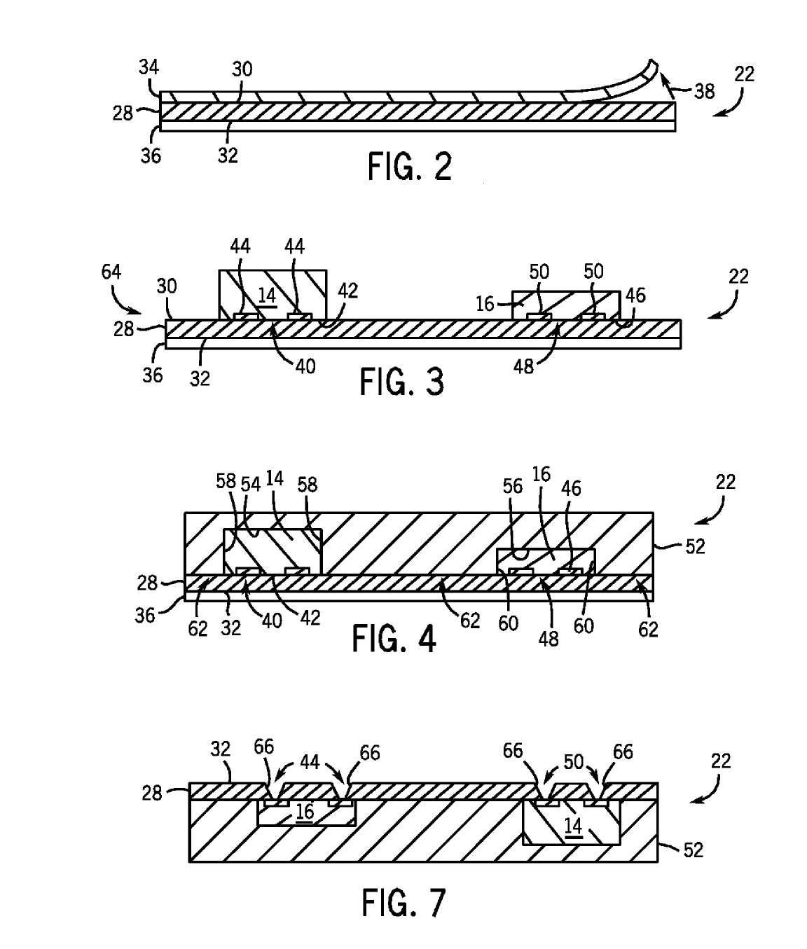

Referring to FIGS. 2-12, a technique for fabricating an IC package 26 is set forth, according to an embodiment of the invention. According to one embodiment, dielectric film 22 may be a thin (e.g., approximately 5 μm) b-staged thermoset film, such as, for example, Adflema™ film acquired from Namics Corporation of Niigata City, Japan. According to another embodiment, dielectric film 22 may be a thermoplastic film. Dielectric film 22 comprises a dielectric layer 28 having homogenous material properties. As shown in FIG. 2, dielectric layer 28 comprises a first side or surface 30, a second side or surface 32, a first sacrificial release liner 34 in contact with first surface 30, and a second release liner 36 in contact with second surface 32. Prior to positioning dies 10-20 (FIG. 1) on dielectric film 22, first sacrificial release liner 34 of dielectric film 22 is removed (as shown by arrow 38) to expose first surface 30. Dies 10-20 may then be positioned face or active side 42 down on first surface 30 of dielectric film 22 as shown below in FIG. 3. As is known, b-staged thermoset materials may become adhesive within a known range of temperatures for the material type. Therefore, the temperature of the dielectric film 22 may be controlled during the fabrication process such that dies 10-20 are held in position solely via an adhesive material property of the dielectric film 22. In one embodiment, dielectric layer 28, and thus first film surface 30, may be adhesive at room temperature. Alternatively, first film surface 30 may become adhesive after heat above room temperature is applied thereto.

As shown in FIG. 3, the fabrication process begins by affixing die 14 to first side or surface 30 of dielectric film 22 at a first contact location 40 such that an active surface 42 of die 14 is directly coupled to first surface 30 of dielectric layer 28. Active surface 42 of die 14 includes any number of contact pads 44 attached thereto. In one embodiment, a well or impression is embossed into dielectric layer 28 at first contact location 40 such that active surface 42 of die 14 is positioned within dielectric layer 28 (i.e., below first surface 30). As described with respect to FIG. 2, because the thermoset material of dielectric layer 28 is an adhesive within a known range of temperatures, the temperature of dielectric layer 28 may be controlled during the fabrication process such that die 14 bonds directly to first surface 30 of dielectric layer 28 and no additional layer of adhesive is needed between die 14 and first surface 30. Alternatively, a heated tip or collet of a pick-and-place machine may be used to heat die 14 prior to placing die 14 on dielectric layer 28. Thus, when heated die 14 is placed at first contact location 40 of dielectric layer 28, heat from die 14 causes first contact location 40 to become adhesive, and die 14 bonds to dielectric layer 28. In a similar manner, an active side or surface 46 of die 16 may be coupled directly to first surface 30 of dielectric film 22 at a second contact location 48 via adhesive properties of dielectric layer 28. Active surface 46 of die 16 includes any number of contact pads 50 attached thereto. Any voids or air gaps between dies 14, 16 and dielectric layer 28 may be removed using vacuum lamination. Together, dies 10-20 and dielectric layer 28 form a reconstituted wafer 64.

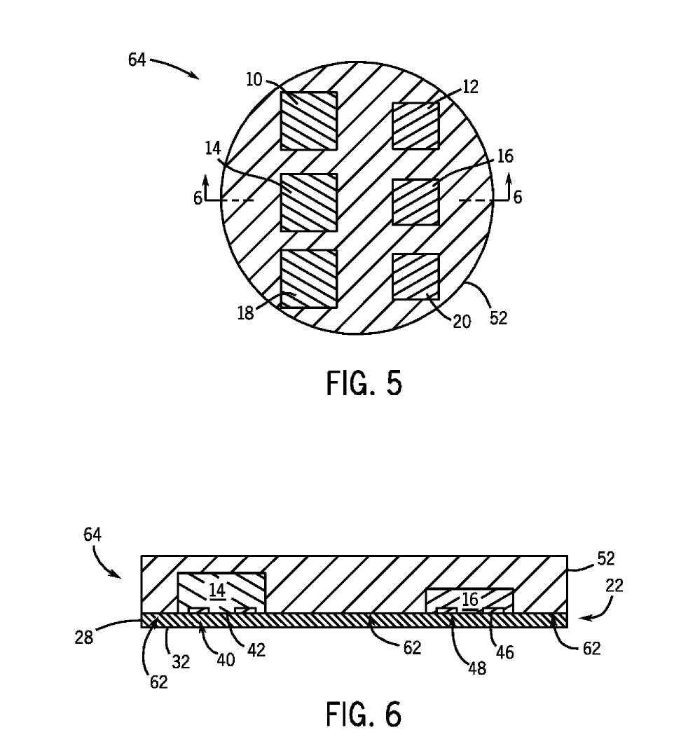

As shown in FIG. 4, after dies 14, 16 are positioned and affixed to dielectric layer 28, an encapsulant or embedding compound 52 is applied to encapsulate bulk surfaces 54, 56 and sides 58, 60 of dies 14, 16, respectively, and coat non-contact locations or portions 62 of dielectric film 22. In one embodiment, encapsulant 52 is an epoxy. Encapsulant 52 and dielectric layer 28 are then allowed to cure. While encapsulant 52 is included in FIGS. 4-12, other embodiments of the invention include no encapsulant 52 and instead use a thicker dielectric film 22 having, for instance, a thickness of up to 150 μm. Referring now to FIGS. 5 and 6 in combination, once encapsulant 52 and dielectric layer 28 have cured, frame 24 (FIG. 1) may be removed and second release liner 36 is removed from dielectric film 22.

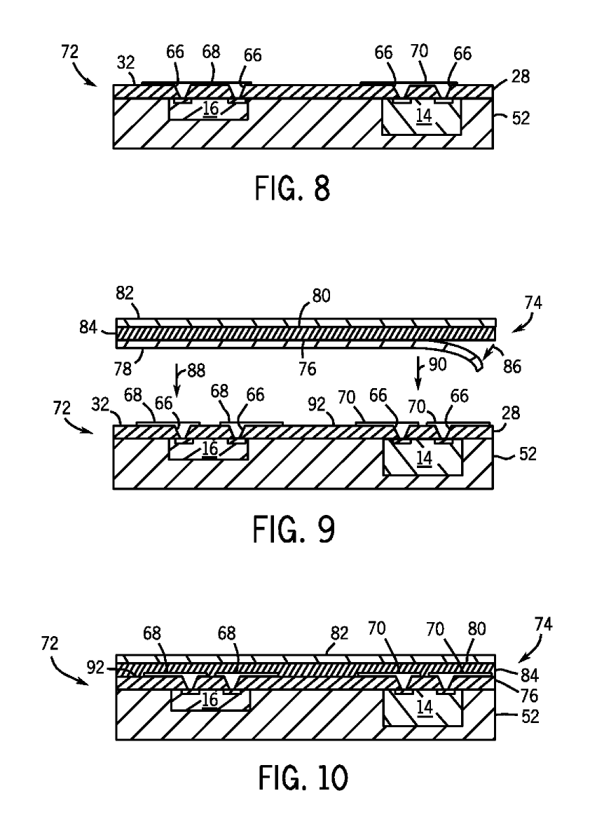

Referring now to FIG. 7, a plurality of vias 66 are formed through dielectric layer 28 to expose contact pads 44 of die 14 and contact pads 50 of die 16. Vias 66 may be formed by, but not limited to, laser drilling or dry etching, for example. As shown in FIG. 8, metallization paths or electrical interconnect layer 68, 70 are formed on second surface 32 of dielectric layer 28 in a next step of the fabrication process. Metallization paths 68, 70 extend through vias 66 and are electrically coupled to contact pads 44, 50 of dies 14, 16, respectively. Metallization paths 68, 70 may comprise, for example, a layer of copper. In one embodiment, metallization paths 68, 70 may be formed using a sputtering and plating technique, followed by a lithography process. Together, metallization paths 68, 70, vias 66, and dielectric layer 28 form a first re-distribution layer 72.

Referring now to FIG. 9, according to one embodiment of the invention, in a next manufacturing step, a second dielectric film 74 is coupled to the first re-distribution layer 72. Similar to dielectric film 22 (FIG. 2), second dielectric film 74 comprises a first film surface 76 covered by a first release liner 78, a second film surface 80 covered by a second release liner 82, and a dielectric layer 84 sandwiched therebetween. According to an exemplary embodiment, dielectric layer 84 may comprise a b-staged thermoset material that acts as an adhesive within a known range of temperatures. To affix first re-distribution layer 72 to dielectric layer 84, first release liner 78 is removed (as shown by arrow 86) and first film surface 76 of second dielectric film 74 is directly coupled (as shown by arrows 88, 90) to a top surface 92 of first re-distribution layer 72. As described above with respect to dielectric layer 28, the adhesive property of dielectric layer 84 causes dielectric layer 84 to bond to first re-distribution layer 72. Therefore, as shown in FIG. 10, an adhesive layer distinct from dielectric layer 84 is not included.

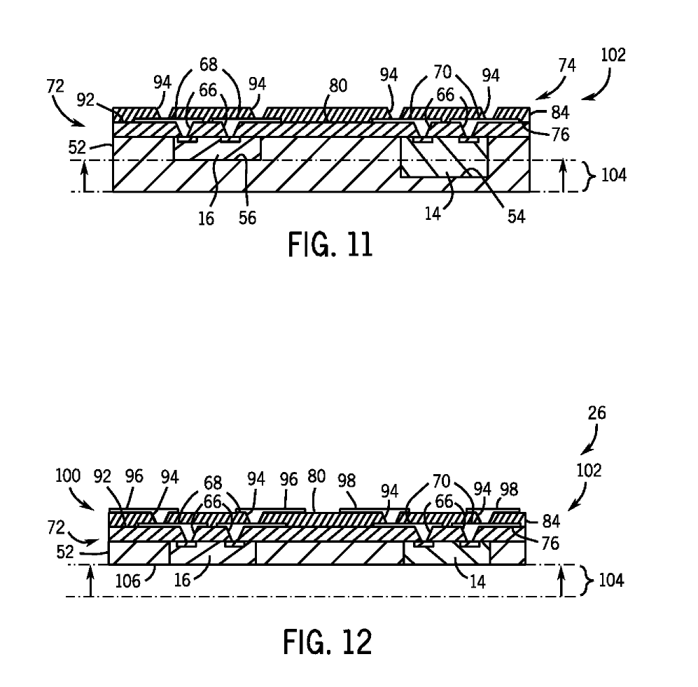

As shown in FIG. 11, in a next step of manufacturing, second release liner 82 of second dielectric film 74 has been removed, and a second plurality of vias 94 are formed through dielectric layer 84 in a similar manner as described with respect to FIG. 5. Metallization paths 96, 98, shown in FIG. 12, are next formed through dielectric layer 84, pass through vias 66 and are electrically coupled to metallization paths 68, 70. Together, metallization paths 96, 98, vias 94, and dielectric layer 84 form a second re-distribution layer 100. Because the thermoset material of dielectric layer 84 itself adheres metallization paths 68, 70 of first re-distribution layer 72 to dielectric 74 of second re-distribution layer 100, a conventional adhesive layer is not needed between adjacent re-distribution layers 72, 100. Together, first re-distribution layer 72 and second re-distribution layer 100 form a re-distribution stack 102. Because a conventional adhesive layer is not included in stack 102, an overall thickness or height of re-distribution layers 72, 100, and therefore, IC package 26, is decreased.

It is contemplated that the process for forming second re-distribution layer 100 described in FIGS. 9-12 may be repeated any number of times to form a re-distribution stack having any desired number of re-distribution layers. Alternatively, any second and/or subsequent re-distribution layer may be constructed using a known method of fabricating a re-distribution layer, such as, for example, spin-coating or spray-coating a dielectric layer onto first re-distribution layer 72 or bonding a dielectric laminate layer, such as Kapton, to first re-distribution layer 72 using a conventional layer of adhesive. The resulting re-distribution layers can be configured in any fashion to aid in second level assembly, for example by solder attachment, or wire bonding to a printed circuit board (PCB) board.

Referring now to FIG. 12, after re-distribution stack 102 is fabricated, an overall thickness or height of IC package 26 may be reduced by removing a thickness 104 of bulk material from encapsulant 52 and dies 14, 16. As shown, the grinding process removes any inconsistencies in the height of dies 14, 16, and IC package 26 may be formed having a planer bottom surface 106. IC package 26 may then be cut into individual chip scale packages (CSP) or multi-chip modules (MCM), which may, for example, be mounted onto conventional printed circuit boards or stacked to form package-on-package (POP) structures.

Accordingly, embodiments of the invention include an IC package having a plurality of individual components or dies, which may be of differing sizes and/or component types. The plurality of individual components or dies are positioned on a dielectric film layer and encapsulated, forming a reconstituted wafer. A stack of individual re-distribution layers are then applied to the reconstituted wafer to connect contact pads on the dies to an input/output system. Because each re-distribution layer includes a dielectric film layer, additional adhesive layers are not needed in the re-distribution stack, thus reducing the overall height of the IC package.

Therefore, according to one embodiment of the invention, an apparatus includes a first dielectric layer comprising a dielectric film having a first side and a second side, the first side having a plurality of contact locations and a plurality of non-contact locations. The apparatus also includes a plurality of components, each component having a first surface and a second surface, wherein the first surface of each of the plurality of components is affixed to a corresponding one of the plurality of contact locations of the dielectric film absent a layer of adhesive therebetween that is distinct from a material of the dielectric film.

According to another embodiment of the invention, an apparatus includes a first dielectric film having a first side and a second side. The apparatus also includes a first component affixed to a first portion of the first side of the first dielectric film via an adhesive property of the first dielectric film and absent a layer of adhesive between the first component and the first dielectric film that is distinct from a property of the first dielectric film.

According to yet another embodiment of the invention, a method of fabricating an integrated circuit (IC) package includes providing a first dielectric film having a first contact side and a second contact side, the first contact side having at least one contact portion and at least one non-contact portion. The method also includes attaching an active surface of at least one electrical component to the at least one contact portion of the first contact side of the first dielectric film via an adhesive property of the first dielectric film and absent a layer of adhesive between the at least one electrical component and the first dielectric film distinct from a property of the first dielectric film. The method further includes curing the first dielectric film and removing a liner of the first dielectric film to expose the second contact side of the first dielectric film.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. An apparatus comprising:
a first dielectric layer comprising a dielectric film having a first side and a second side, the first side having a plurality of contact locations and a plurality of non-contact locations; and
a plurality of components, each component having a first surface and a second surface, wherein the first surface of each of the plurality of components is affixed to a corresponding one of the plurality of contact locations of the dielectric film absent a layer of adhesive therebetween that is distinct from a material of the dielectric film.

2. The apparatus of claim 1 further comprising an embedding compound encapsulating the plurality of components and coating the plurality of non-contact locations of the dielectric film.

3. The apparatus of claim 1 further comprising a first metallization layer having a bottom surface and a top surface, wherein the bottom surface is affixed to the second side of the dielectric film.

4. The apparatus of claim 3 further comprising a second dielectric layer having a first contact side and a second contact side, the first contact side affixed to the top surface of the first metallization layer; and
a second metallization layer affixed to the second contact side of the second dielectric layer.

5. The apparatus of claim 4 wherein the second dielectric layer comprises a second dielectric film.

6. The apparatus of claim 4 wherein the second dielectric layer comprises one of a dielectric material spin-coated on the first metallization layer and a dielectric lamination affixed to the first metallization layer via an adhesive layer.

7. The apparatus of claim 1 wherein a distance between the first surface and the second surface of each of the plurality of components comprises a component thickness, the die thickness of each of the plurality of dies being substantially similar to an embedding compound thickness.

8. The apparatus of claim 1 wherein the plurality of components comprises at least one of a first type of component and at least one of a second type of component.

9. The apparatus of claim 1 wherein the first dielectric layer comprises one of a thermoset material and a thermoplastic material.

10. An apparatus comprising:
a first dielectric film having a first side and a second side;
a first component affixed to a first portion of the first side of the first dielectric film via an adhesive property of the first dielectric film and absent a layer of adhesive between the first component and the first dielectric film that is distinct from a property of the first dielectric film.

11. The apparatus of claim 10 further comprising an encapsulant abutting the first component and affixed to a second portion of the first side of the first dielectric film.

12. The apparatus of claim 10 further comprising a plurality of electrical interconnects formed on the first dielectric film and extending from the second side of the first dielectric film to the first component through the first dielectric film, the plurality of electrical interconnects in electrical contact with at least one contact pad of the first component.

13. The apparatus of claim 12 further comprising a dielectric layer affixed to a top surface of the plurality of electrical interconnects.

14. The apparatus of claim 13 wherein the dielectric layer comprises one of a second dielectric film and a spun-on dielectric coating.

15. The apparatus of claim 13 wherein the dielectric layer comprises an adhesive layer and a dielectric lamination, the adhesive layer bonding the dielectric layer to the plurality of electrical interconnects.

16. The apparatus of claim 10 further comprising a second component affixed to the first side of the first dielectric film.

17. The apparatus of claim 16 wherein the first component comprises a first type of semiconductor chip and the second component comprises a second type of semiconductor chip.

18. The apparatus of claim 17 wherein the first type of semiconductor chip and the second type of semiconductor chip are selected from the group consisting of a memory chip type, a processing chip type, a logic chip type, and an application specific integrated circuit (ASIC) chip type.

19. The apparatus of claim 10 wherein the first component is one of a semiconductor die, an active electronic device, and a passive electronic device.

20. A method of fabricating an integrated circuit (IC) package comprising:
providing a first dielectric film having a first contact side and a second contact side, the first contact side having at least one contact portion and at least one non-contact portion;
attaching an active surface of at least one electrical component to the at least one contact portion of the first contact side of the first dielectric film via an adhesive property of the first dielectric film and absent a layer of adhesive between the at least one electrical component and the first dielectric film distinct from a property of the first dielectric film;
curing the first dielectric film; and
removing a liner of the first dielectric film to expose the second contact side of the first dielectric film.

21. The method of claim 20 further comprising encapsulating the at least one electrical component and the at least one non-contact portion of the first dielectric film in an embedding compound.

22. The method of claim 21 wherein curing further comprises curing the embedding compound.

23. The method of claim 20 wherein attaching comprises attaching an active surface of each of a plurality of electrical components to the first contact side of the first dielectric film.

24. The method of claim 20 further comprising heating the first contact side of the first dielectric film prior to attaching the at least one electrical component thereto.

25. The method of claim 20 further comprising forming a first metallization layer on the second contact side of the first dielectric film.

26. The method of claim 25 further comprising:
forming a first plurality of vias through the first dielectric film to the active surface of the at least one electrical component; and
wherein forming the first metallization layer comprises coupling a plurality of metallization paths from the second contact side of the first dielectric film to the active surface of the at least one electrical component through the first plurality of vias.

27. The method of claim 25 further comprising attaching a first contact side of a second dielectric layer to the metallization layer.

28. The method of claim 27 further comprising removing a portion of the second dielectric layer to expose a second plurality of vias therethrough to the first metallization layer; and
forming a second metallization layer on a second contact side of the second dielectric layer to extend through the second plurality of vias and contact the first metallization layer.

29. The method of claim 27 wherein attaching the first contact side of the second dielectric layer to the metallization layer comprises securing one of a spin-coated dielectric and a first side of a second dielectric film to the metallization layer.

30. The method of claim 27 wherein attaching the first contact side of the second dielectric layer to the metallization layer comprises adhering a dielectric lamination to the metallization layer via a layer of adhesive.

31. The method of claim 20 further comprising removing a portion of bulk material from the at least one electrical component to reduce an overall height of the IC package.
